(19) United States
(12) Patent Application Publication
(10) Pub. No.: US 2024/0339564 A1
(43) Pub. Date: Oct. 10, 2024

(54) SEMICONDUCTOR DEVICE

(71) Applicant: EPISTAR CORPORATION, Hsinchu (TW)

(72) Inventors: Wei-Che WU, Hsinchu (TW); Chih-Hao CHEN, Hsinchu (TW); Yu-Ling LIN, Hsinchu (TW); Chao-Hsing CHEN, Hsinchu (TW); Yong-Yang CHEN, Hsinchu (TW)

(21) Appl. No.: 18/625,617

(22) Filed: Apr. 3, 2024

(30) Foreign Application Priority Data
Apr. 6, 2023 (TW) 112112756
Feb. 27, 2024 (TW) 113107062

(51) Int. Cl. H01L 33/22; H01L 33/00; H01L 33/60

(52) U.S. Cl. CPC H01L 33/22; H01L 33/005; H01L 33/60

(57) ABSTRACT

A semiconductor device includes a semiconductor stack; a substrate formed on the semiconductor stack, including a lower surface connected to the semiconductor stack, an upper surface opposite to the lower surface, and a side surface between the lower surface and the upper surface, wherein the side surface includes a mirror area, a first scribing area, and a first crack area, the mirror area is closer to the lower surface than the first scribing area to the lower surface, and the first scribing area is located between the mirror area and the first crack area; an optical structure on the upper surface of the substrate; and a reflective structure on a side surface of the first scribing area and the first crack area, wherein the first scribing area is arranged below the upper surface of the substrate with a distance less than or equal to ¼ of a thickness of the substrate.

### TECHNICAL FIELD

The application relates to a semiconductor device, and more particularly, to a semiconductor device including a substrate in which a side wall of the substrate includes an uneven surface.

### REFERENCE TO RELATED APPLICATION

This application claims the right of priority based on TW application Ser. No. 11/310,7062, filed on Feb. 27, 2024, which claims the right of priority based on TW application Ser. No. 11/211,2756, filed on Apr. 6, 2023, and the contents of which are hereby incorporated by reference in their entireties.

### DESCRIPTION OF BACKGROUND ART

The semiconductor device includes semiconductor compounds composed of III-V group elements, such as gallium phosphide (GaP), gallium arsenide (GaAs), gallium nitride (GaN), and aluminum nitride (AlN). The semiconductor device can be a semiconductor optoelectronic device, such as a light-emitting diode (LED), a laser, a photo detector, or a solar cell. The semiconductor device also can be a power device or an acoustic wave device. Taking the light-emitting diode (LED) as an example, the light-emitting diode is a solid-state semiconductor light-emitting device, which has the advantages of low power consumption, low heat generation, long working lifetime, shockproof, small volume, fast reaction speed, and good photoelectric property, such as stable emission wavelength. Therefore, the light-emitting diode is widely used in the household appliance, the equipment indicator, and the optoelectronic product. Since the surface of the transparent substrate of the conventional light-emitting device is flat, and the refractive index of the transparent substrate is different from that of the external environment, the total internal reflection (TIR) is easily formed when the light emitted from the active layer enters the external environment from the transparent substrate, which reduces the light extraction efficiency of the light-emitting device.

### SUMMARY OF THE APPLICATION

A semiconductor device includes a semiconductor stack; a substrate formed on the semiconductor stack, including a lower surface connected to the semiconductor stack, an upper surface opposite to the lower surface, and a side surface between the lower surface and the upper surface, wherein the side surface includes a mirror area, a first dicing area, and a first crack area, the mirror area is closer to the lower surface than the first dicing area to the lower surface, and the first dicing area is located between the mirror area and the first crack area; an optical structure formed on the upper surface of the substrate; and a reflective structure formed on a side surface of the first dicing area and the first crack area, wherein the first dicing area is arranged below the upper surface of the substrate with a distance less than or equal to ¼ of a thickness of the substrate.

### BRIEF DESCRIPTION OF THE DRAWINGS

FIG. 1A illustrates a cross-sectional view of a light-emitting device 1a in accordance with an embodiment of the present application;

FIG. 1B illustrates a partially enlarged view of the dicing convex portion and the crack convex portion in FIG. 1A in accordance with an embodiment of the present application;

FIG. 1C illustrates a partially enlarged view of the dicing convex portion and the crack convex portion in FIG. 1A in accordance with an embodiment of the present application;

FIG. 2 illustrates a cross-sectional view of a light-emitting device 1b in accordance with an embodiment of the present application;

FIG. 3 illustrates a cross-sectional view of a light-emitting device 1c in accordance with an embodiment of the present application;

FIG. 4 illustrates a relationship between a distance D below an upper surface of the substrate where the first dicing area of the light-emitting device 1a, 1b, or 1c is located and the light extraction efficiency (%) thereof in accordance with an embodiment of the present application;

FIG. 5 illustrates a relationship between a width W of the first dicing area of the light-emitting device 1a, 1b, or 1c and the light extraction efficiency (%) thereof in accordance with an embodiment of the present application;

FIG. 6 illustrates a topography of the first dicing area in accordance with an embodiment of the present application;

FIG. 7 illustrates a partially topography of the side surface of the substrate in accordance with an embodiment of the present application;

FIG. 8 illustrates an angle between a first surface of the light-emitting device 1a and the upper surface of the substrate, and the angle between the first surface of the light-emitting device 1c and the upper surface of the substrate;

FIG. 9 illustrates the measured lengths of the light-emitting device 1a and the light-emitting device 1c;

FIG. 10A illustrates an SEM photograph of the light-emitting device 1c;

FIG. 10B illustrates a relationship curve between the light intensity and the luminous angle of a light emitted from the light-emitting device 1c viewed in a first direction;

FIG. 10C illustrates the light intensity at +15 and +30 degrees off a main axis of the light viewed in the first direction;

FIG. 10D illustrates an SEM photograph of the light-emitting device 1c;

FIG. 10E illustrates a relationship curve between the light intensity and the luminous angle of the light emitted from the light-emitting device 1c viewed in a second direction;

FIG. 10F illustrates the light intensity at +15 and +30 degrees off the main axis of the light viewed in the second direction;

FIG. 11A illustrates an SEM photograph of the light-emitting device 1a;

FIG. 11B illustrates a relationship curve between the light intensity and the luminous angle of the light emitted from the light-emitting device 1a viewed in a first direction;

FIG. 11C illustrates the light intensity at +15 and +30 degrees off a main axis of the light viewed in the first direction;

FIG. 11D illustrates an SEM photograph of the light-emitting device 1a;

FIG. 11E illustrates a relationship curve between the light intensity and the luminous angle of the light emitted from the light-emitting device 1a viewed in a second direction;

FIG. 11F illustrates the light intensity at +15 and +30 degrees off a main axis of the light viewed in the second direction;

FIG. 12 illustrates a cross-sectional view of a light-emitting apparatus 2 in accordance with an embodiment of the present application;

FIG. 13 illustrates a cross-sectional view of a light-emitting apparatus 6 in accordance with an embodiment of the present application; and

FIG. 14 illustrates a cross-sectional view of a light-emitting apparatus 7 in accordance with an embodiment of the present application.

### DETAILED DESCRIPTION OF PREFERRED EMBODIMENTS

The embodiment of the application is illustrated in detail, and is plotted in the drawings. The same or the similar part is illustrated in the drawings and the specification with the same number.

In accordance with an embodiment, the semiconductor device can be a semiconductor optoelectronic device such as a light-emitting diode (LED), a laser, a photo detector, a solar cell, or a power device. Taking the light-emitting device as an example of the semiconductor device, the main structure includes a buffer layer and a device structure formed on the buffer layer. Different device structures are provided depending on the device function of the semiconductor device. For example, the device structure of the light-emitting device includes a semiconductor light-emitting stack including a p-type semiconductor layer, an n-type semiconductor layer and an active region, and the active region includes a light-emitting layer, which can emit light with different wavelengths depending on the material composition thereof. The embodiments are provided below as relevant descriptions of the semiconductor devices. However, it can be understood that the semiconductor devices in these embodiments are only for illustration and are not intended to limit the present application.

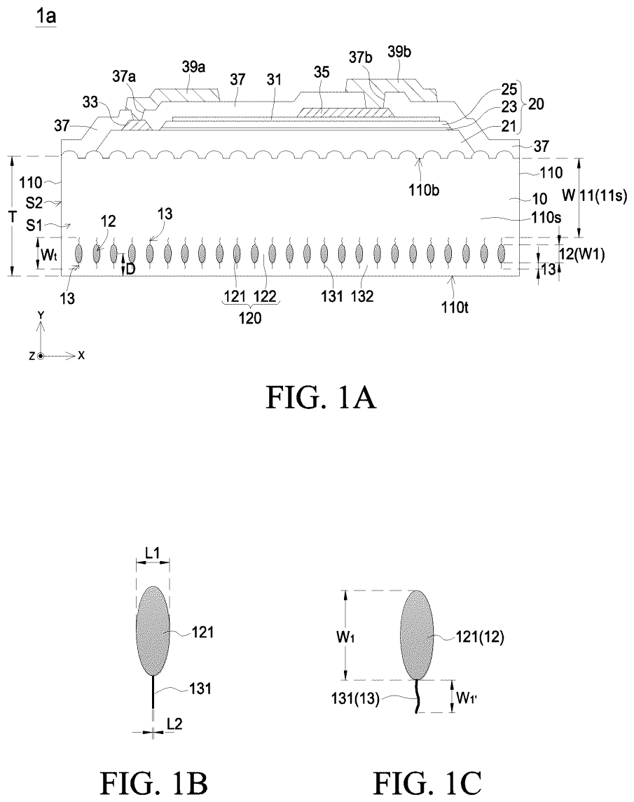

In detail, the following embodiments are examples in which the light-emitting device is illustrated as the semiconductor device. FIG. 1A illustrates a cross-sectional view of a light-emitting device 1a according to an embodiment of the present application, wherein the cross-sectional view in FIG. 1A corresponds to a plane formed by the X direction and the Y direction. The light-emitting device 1a includes a semiconductor stack 20, a substrate 10 including a lower surface 110b connected to the semiconductor stack 20, an upper surface 110t opposite to the lower surface 110b, and a side surface 110s located between the lower surface 110b and the upper surface 110t, wherein the side surface 110s includes two sides 110. Specifically, the side 110 can be an intersection between two adjacent side surfaces 110s. The side surface 110s includes a mirror area 11, a first dicing area 12, and a first crack area 13. The mirror area 11 is closer to the lower surface 110b than the first dicing area 12 to the lower surface 110b, and the first dicing area 12 is located between the mirror area 11 and the first crack area 13.

In an embodiment, the substrate 10 can be a growth substrate for epitaxially growing the buffer layer (not shown) and the semiconductor stack 20. The substrate 10 includes a gallium arsenide (GaAs) wafer for the epitaxial growth of aluminum gallium indium phosphide (AlGaInP), or a sapphire (Al₂O₃) wafer, a gallium nitride (GaN) wafer, a silicon carbide (SiC) wafer, or an aluminum nitride (AlN) wafer for the epitaxial growth of gallium nitride (GaN), indium gallium nitride (InGaN), or aluminum gallium nitride (AlGaN), but the present application is not limited to this, other substrate materials are also suitable for use in this application.

In an embodiment of the present application, the metal organic chemical vapor deposition (MOCVD), molecular beam epitaxy (MBE), hydride vapor phase (HVPE), physical vapor deposition (PVD), or the ion plating method is provided to form the buffer layer (not shown) and the semiconductor stack 20 including a first doped semiconductor layer 21, a light-emitting layer 23, and a second doped semiconductor layer 25 on the substrate 10, wherein the physical vapor deposition method includes sputtering or evaporation.

In an embodiment, the first doped semiconductor layer 21 includes an n-type doped III-V semiconductor, for example, an n-type doped binary, ternary, or quaternary III-V semiconductor. In some embodiments, the n-type doped binary III-V semiconductor includes n-type doped gallium nitride (GaN), but the present application is not limited thereto. Other suitable n-type doped binary III-V semiconductors are also applicable to this application. In some embodiments, the n-type doped ternary III-V semiconductor includes n-type doped indium gallium nitride (InGaN) or aluminum gallium nitride (AlGaN), but the application is not limited thereto. Other suitable n-type doped ternary III-V semiconductors are also applicable to this application. In some embodiments, the n-type doped quaternary III-V semiconductor includes n-type doped indium aluminum gallium nitride (InAlGaN), but the application is not limited thereto. Other suitable n-type doped quaternary III-V semiconductors are also applicable to this application. The n-type doping includes silicon (Si), carbon (C), germanium (Ge), or oxygen (O), but the present application is not limited thereto, and other suitable Group IV or Group VI elements are also applicable to the present application.

In an embodiment, the light-emitting layer 23 includes III-V group semiconductor materials, such as InGaN series materials, AlGaN series materials or AlInGaN series materials. When the material of the light-emitting layer 23 includes the InGaN series materials, the light-emitting layer 23 can emit a blue light with a wavelength between 400 nm and 490 nm, a cyan light with a wavelength between 490 nm and 530 nm, or a green light with a wavelength between 530 nm and 570 nm. When the material of the light-emitting layer 23 is AlGaN series or AlInGaN series, the light-emitting layer 23 can emit an ultraviolet light with a wavelength between 400 nm and 250 nm. In an embodiment, the light-emitting layer 23 includes a single heterostructure, a double heterostructure or a multiple quantum well structure. In an embodiment, the material of the light-emitting layer 23 can be an i-type, p-type or n-type semiconductor. In the embodiment, the light-emitting layer 23 includes a multiple-quantum well (MQW) structure. For example, one or more well layers made of indium gallium nitride (InGaN) material, and one or more barrier layers having an energy barrier higher than that of the well layer and/or made of gallium nitride (GaN) or aluminum gallium nitride (AlGaN) materials are alternately stacked. However, the application is not limited thereto includes, the multiple quantum well structure composed of alternately stacked well layers and barrier layers based on other suitable III-V group semiconductor materials is also applicable to the present application.

In some embodiments, the second doped semiconductor layer 25 includes a p-type doped III-V semiconductor, for example, a p-type doped binary, ternary, or quaternary III-V semiconductor. In some embodiments, the p-type doping includes magnesium (Mg), beryllium (Be), calcium (Ca), or strontium (Sr), but the present application is not limited thereto, and other suitable Group II elements are also applicable to the present application. In some embodiments, the p-type doped binary III-V semiconductor includes p-type doped gallium nitride (GaN), but the application is not limited thereto. Other suitable p-type doped binary III-V semiconductors are also applicable to this application. In some embodiments, the p-type doped ternary III-V semiconductor includes p-type doped indium gallium nitride (InGaN), aluminum indium nitride (AlInN), or aluminum gallium nitride (AlGaN), However, the present application is not limited thereto, and other suitable p-type doped ternary III-V group semiconductors are also applicable to the present application. In some embodiments, the p-type doped quaternary III-V semiconductor includes p-type doped indium aluminum gallium nitride (InAlGaN), but the present application is not limited thereto. Other suitable p-type doped quaternary III-V semiconductors are also applicable to this application.

The light-emitting device 1a includes a transparent conductive layer 31 (for example, indium tin oxide (ITO)) formed on the second doped semiconductor layer 25, a protective layer 37 conformally formed on the semiconductor stack 20, a first conductive contact 33 electrically connected to the first doped semiconductor layer 21, a second conductive contact 35 electrically connected to the second doped semiconductor layer 25, a first conductive pad 39 passing through a protective layer first opening 37a of the protective layer 37 to electrically connect the first conductive contact 33, and a second conductive pad 39b passing through a protective layer second opening 37b of the protective layer 37 to electrically connected the second conductive contact 35.

Since the light of the light-emitting device 1a can be emitted from the upper surface 110t of the substrate 10 and the multiple side surfaces 110s, in order to reflect the light on the side surfaces 110s and emit the light from the upper surface 110t of the substrate 10, the present application provides a first dicing area 12 including a concave-convex structure 120 on the side surface 110s of the substrate 10 and adjusts the position of the first dicing area 12 to improve the external light extraction efficiency (LEE). The first dicing area 12 includes the concave-convex structure 120. The concave-convex structure 120 includes a plurality of dicing convex portions 121 and a plurality of dicing concave portions 122, which are separately formed on the side surface 110s of the substrate 10 along the X direction in FIG. 1A. The plurality of dicing convex portions 121 and the plurality of dicing concave portions 122 can be disposed on the side surface 110s of the substrate 10 at equal or unequal intervals to form the concave-convex structure 120.

The concave-convex structure 120 of the present application includes V shape, trapezoidal shape, rectangular shape, arc shape, semi-circular shape, semi-elliptical shape and/or any other shapes. Viewed along the X direction or Y direction of FIG. 1A, the concave-convex structure 120 of the present application include trapezoidal shape, rectangular shape, circular shape, semi-circular shape, elliptical shape, semi-elliptical shape and/or any other shapes. In an embodiment, the shapes of the concave-convex structure 120 in the X direction and in the Y direction are different. In an embodiment, in the X direction and the Y direction of FIG. 1A, the side view profile shapes of the concave-convex structure 120 in different directions or in the same direction can be different.

The concave-convex structure 120 of the present application includes a dimension, such as the extension length, the spacing, the width, the height relative to the mirror surface 11s of the mirror area 11 of the substrate 10, or the depth relative to the mirror surface 11s of the mirror area 11 of the substrate 10, which can be measured through an atomic force microscope (AFM) or a scanning electron microscope (SEM).

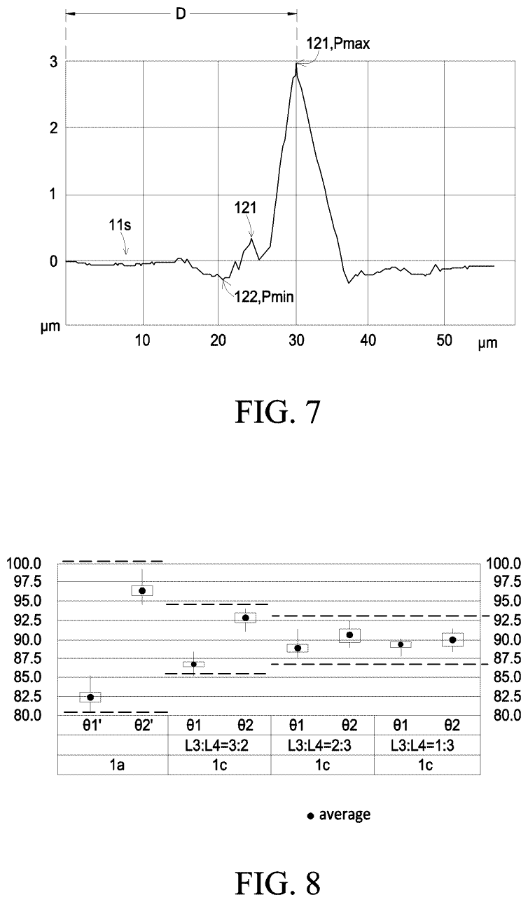

FIG. 6 illustrates a topographic view of the first dicing area 12 scanned along the X direction of FIG. 1A through the atomic force microscope according to an embodiment of the present application. FIG. 7 illustrates a partially topographic view of the side surface 110s of the substrate 10 scanned along the Y direction of FIG. 1A through the atomic force microscope according to an embodiment of the present application. Compared with the mirror surface 11s of the mirror area 11, the concave-convex structure 120 of the first dicing area 12 is inclined to the mirror surface 11s of the mirror area 11 in the Z direction. For example, the dicing convex portion 121 protrudes from the mirror surface 11s of the mirror area 11 along the (+) Z direction in FIG. 1A and the dicing concave portion 122 recesses into the mirror surface 11s of the mirror area 11 along the (−) Z direction in FIG. 1A. The two adjacent dicing convex portions 121 and the dicing concave portions 122 respectively includes a highest point Pₘₐₓ and a lowest point Pₘᵢₙ. The spacing P between the highest point Pₘₐₓ and the lowest point Pₘᵢₙ projected on the X-Y plane is greater than the peak value of the wavelength λ of the light emitted from the light-emitting layer 23 to increase the light extraction efficiency of the light-emitting device 1a, 1b, or 1c. For example, the spacing P can be 2 to 20 times the peak value of the wavelength λ. In an embodiment, the mirror surface is defined to be a flat surface having a surface roughness smaller in dimension. In an embodiment, as shown in FIG. 7, the mirror surface 11s of the mirror area 11 includes a roughness standard deviation (RMS) less than 150 nanometers (nm). The roughness standard deviation (RMS) can be obtained by the formula

$$R M S = \sqrt{\frac{\sum {Zi}^{2}}{n}} ,$$

where n is the measurement points in the sampling area, and Zi is the measurement value of the height or the depth of each of measurement points in the sampling area.

In an embodiment, as shown in FIG. 1A and FIG. 7, the first dicing area 12 is located under the upper surface 110t of the substrate 10 at a distance D that is less than or equal to ¼ of the thickness T of the substrate 10. Scanning a rectangular area of 1 μm×50 μm along a direction from the upper surface to the lower surface 110b of the substrate 10 through the atomic force microscope (AFM), for example, an area composed of the X direction and the Y direction, the distance D can be defined as the distance between the upper surface 110t of the substrate 10 and the highest point Pₘₐₓ of the dicing convex portion 121 (as shown in FIG. 7) or the distance between the upper surface 110t of the substrate 10 and the lowest point Pₘᵢₙ of the dicing concave portion 122 (not shown).

As shown in FIG. 1A, the mirror area 11 includes a width W. In an embodiment, the width W can be larger than 75 μm. In an embodiment, the first dicing area 12 can be located under the upper surface 110t of the substrate 10 by a distance D less than 45 μm, 35 μm, 25 μm, or 15 μm. In order to effectively form the first dicing area 12, in an embodiment, the distance D under the upper surface 110t of the substrate 10 where the first dicing area 12 is located is larger than 0.1 μm or 1 μm. In the Y direction of FIG. 1A, as shown in FIG. 1A and FIG. 1C, the first dicing area 12 includes a first dicing width W1 between 4 μm and 30 μm. The first dicing area 12 and the first crack area 13 include a total width Wₜ smaller than the width W of the mirror area 11. In an embodiment, the thickness T of the substrate 10 can be 60 μm˜220 μm or 100 μm˜150 μm. In an embodiment, the first dicing area 12 can be defined to be protruding from the mirror area 11 with a height greater than or equal to 0.1 μm in the (+) Z direction in FIG. 1A, and the first crack area 13 can be defined to be recessed into the mirror area 11 with a depth greater than or equal to 0.1 μm in the (−) Z direction in FIG. 1A.

Viewed along the X direction or Y direction in FIG. 1A, the dicing convex portion 121 and the dicing concave portion 122 have a cone shape or a frustum shape. The dicing convex portion 121 includes a height in the (+) Z direction in FIG. 1A. In an embodiment, the height is between 0.1 μm and 5 μm. In another embodiment, the height is between 1 μm and 3.5 μm. In another embodiment, the height is between 2 μm and 3 μm. The dicing concave portion 122 includes a depth in the (−) Z direction in FIG. 1A. In an embodiment, the depth is between 0.1 μm and 5 μm. In another embodiment, the depth is between 1 μm and 3.5 μm. In another embodiment, the depth is between 2 μm and 3 μm. In the Z direction in FIG. 1A, the spacing is between the two adjacent points of the highest point of the dicing convex portion 121 and the lowest point of the dicing concave portion 122 projected on the XY plane. In an embodiment, the spacing is between 0.2 μm and 10 μm. In another embodiment, the spacing is between 2 μm and 7 μm. In another embodiment, the spacing is between 4 μm and 6 μm. Compared with the mirror surface 11s of the mirror area 11, the side surface of the dicing convex portion 121 or the dicing concave portion 122 includes an angle between 15° and 75° inclined to the side surface 110s of the substrate 10 composed by the X direction and Y direction in FIG. 1A.

In an embodiment, the shapes and sizes of the plurality of dicing convex portions 121 can be the same or different, the shapes and sizes of the plurality of dicing concave portion 122 can be the same or different, and/or the shapes and sizes between the dicing convex portion 121 and the dicing concave portion 122 can be the same or different.

In an embodiment, on the same scanning area, the roughness standard deviation (RMS) of the first dicing area 12 is larger than that of the first crack area 13, and the roughness standard deviation (RMS) of the first crack area 13 is larger than that of the mirror area 11.

The manufacturing method of the first dicing area 12 includes but not limited to nanoimprinting or forming a mask through a photolithography process, and then forming the concave-convex structure 120 of the first dicing area 12 through an etching process. In an embodiment, the laser can be irradiated from the upper surface 110t of the substrate 10, focused on the interior of the substrate 10, and moved along a boundary line of the light-emitting device 1a (for example, the X direction in FIG. 1A) to form the first dicing area 12.

The first crack area 13 includes a plurality of crack convex portions 131 and/or a plurality of crack concave portions 132 extending from the first dicing area 12 in an irregular direction and a non-fixed length toward the upper surface 110t of the substrate 10. In an embodiment, the crack convex portion 131 can branch from the dicing convex portion 121 or the dicing concave portion 122 of the first dicing area 12 to form a one-to-one arrangement. The crack concave portion 132 can branch at a position different from the crack convex portion 131 from the dicing convex portion 121 or the dicing concave portion 122 in the first dicing area 12 to form a one-to-one arrangement. In another embodiment, the crack convex portion 131 and/or the crack concave portion 132 only branches from a part of the dicing convex portions 121 or the dicing concave portions 122, so that the amount of the crack convex portions 131 is less than the amount of the dicing convex portions 121, the amount of the crack convex portions 131 is less than the amount of the dicing concave portions 122, the amount of the crack concave portions 132 is less than the amount of the dicing convex parts 121, or the amount of the crack concave portions 132 is less than the amount of the dicing concave portions 122. The extending directions or spacings of the plurality of crack convex portions 131 and/or the plurality of crack concave portions 132 can be the same or different from each other. Therefore, the spacing between the plurality of the crack convex portions 131 can be different from the spacing between the plurality of the dicing convex portions 121.

The plurality of dicing convex portions 121 and/or the plurality of dicing concave portions 122 includes an amount or a size greater than or smaller than that of the plurality of crack convex portions 131 and/or the plurality of crack concave portions 132. FIG. 1B and FIG. 1C illustrate a partially enlarged view of the dicing convex portion 121 and the crack convex portion 131 shown in FIG. 1A according to an embodiment of the present application. In an embodiment, along the X direction in FIG. 1A, the dicing convex portion 121 includes a dicing extension length L1 greater than the crack extension length L2 of the crack convex portion 131. In an embodiment (not shown), along the X direction in FIG. 1A, the dicing extension length L1 of the dicing convex portion 121 can be smaller than the crack extension length L2 of the crack convex portion 131. In another embodiment, along the Y direction in FIG. 1A, the dicing convex portion 121 located in the first dicing area 12 includes a first dicing width W1 smaller or larger than a first crack width W1′ of the crack convex portion 131 located in the first crack area 13. In another embodiment, along the Z direction in FIG. 1A, the dicing convex portion 121 or the dicing concave portion 122 includes a height or a depth that is greater than the height or depth of the crack convex portion 131 or the crack concave portion 132. The minimum spacing between the plurality of dicing convex portions 121 and/or between the plurality of dicing concave portions 122 is smaller than the minimum spacing between the plurality of crack convex portions 131 and/or between the plurality of crack concave portions 132.

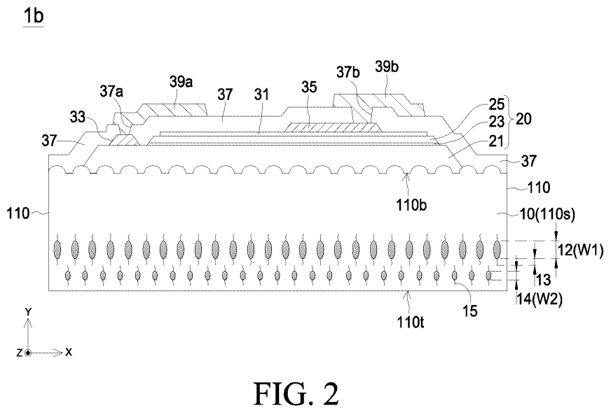

FIG. 2 illustrates a cross-sectional view of a light-emitting device 1b according to an embodiment of the present application, wherein FIG. 2 corresponds to the plane formed by the X direction and the Y direction. The materials and dimensions of the substrate 10, the semiconductor stack 20, the transparent conductive layer 31, the protective layer 37, the first conductive contact 33, the second conductive contact 35, the first conductive pad 39a and the second conductive type pad 39b of the light-emitting device 1b disclosed in FIG. 2 are similar to the materials and dimensions of the elements of the light-emitting device 1a disclosed in FIG. 1A, and those will not be described again here.

As shown in FIG. 2, the light-emitting device 1b further includes a second dicing area 14 located between the first dicing area 12 and the upper surface 110t of the substrate 10, so that the second dicing area 14 is closer to the light-emitting surface (the upper surface 110t of the substrate 10) of the light-emitting device 1b and the light extraction efficiency (LEE) of the light-emitting device 1b is improved. The first crack area 13 is located between the first dicing area 12 and the second dicing area 14. In the Y direction of FIG. 2, the first dicing width W1 of the first dicing area 12 can be greater than, smaller than, or the same as the second dicing width W2 of the second dicing area 14.

In an embodiment, the light-emitting device 1b further includes a second crack area 15 located between the second dicing area 14 and the upper surface 110t of the substrate 10, so that the second crack area 15 is closer to the light emitting surface (the upper surface 110t of the substrate 10) of the light-emitting device 1b and the light extraction efficiency (LEE) of the light-emitting device 1b is improved. The structure and size of the second crack area 15 are similar to the structure and size of the first crack area 13 disclosed in FIG. 1A and those will not be described again here.

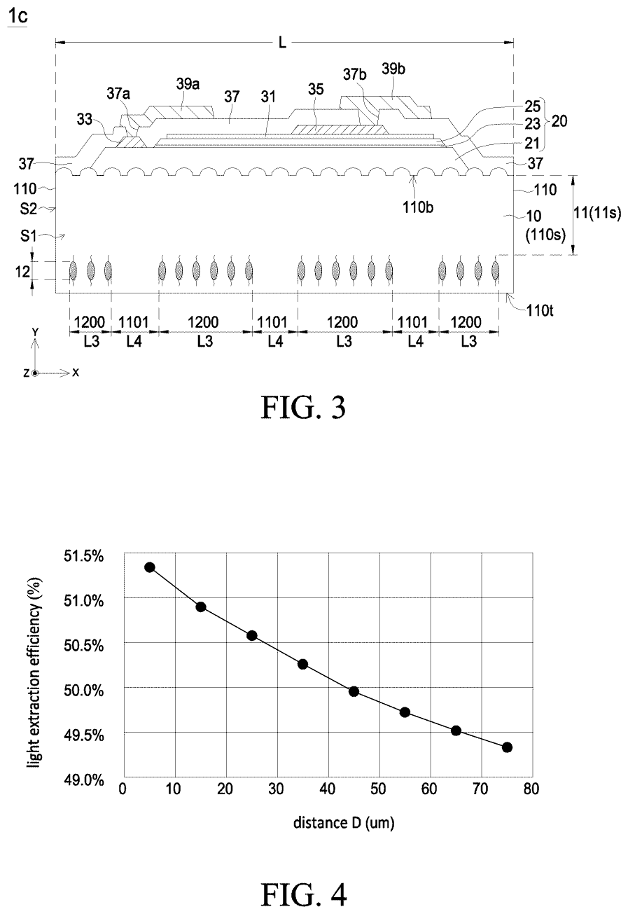

FIG. 3 illustrates a cross-sectional view of a light-emitting device 1c according to an embodiment of the present application, wherein FIG. 3 corresponds to the plane formed by the X direction and the Y direction. The materials and dimensions of the substrate 10, the semiconductor stack 20, the transparent conductive layer 31, the protective layer 37, the first conductive contact 33, the second conductive contact 35, the first conductive pad 39a and the second conductive pad 39b of the light-emitting device 1c disclosed in FIG. 3 are similar to the materials and dimensions of the elements of the light-emitting device 1a disclosed in FIG. 1A, and those will not be described again here.

In an embodiment of the application, the flat surface area of the side surface 110s of the substrate 10 is increased to expand the mirror area 11 to improve the light extraction efficiency (LEE) of the light-emitting device 1c.

As shown in FIG. 3, the mirror area 11 of the light-emitting device 1c includes a plurality of mirror portions 1101 passing through the first dicing area 12 to divide the first dicing area 12 into a plurality of first dicing portions 1200. In an embodiment, the mirror portion 1101 is defined to be a flat surface having a surface roughness smaller in dimension, for example, the mirror portion 1101 includes a roughness standard deviation (RMS) less than 150 nm. In the X direction, one of the plurality of first dicing portions 1200 includes a first length L3 greater than or equal to a second length L4 of one of the plurality of mirror portions 1101. In the side view of the light-emitting device 1c, the second length L4 of the mirror portion 1101 is 0.5˜0.8 times the length L of one side of the light-emitting device 1c. In an embodiment, the first length L3 of the first dicing portion 1200 is greater than the second length L4 of the mirror portion 1101. In an embodiment, a ratio (L4/L3) between the second length L4 of the mirror portion 1101 and the first length L3 of the first dicing portion 1200 is 0.2˜0.8, 0.25˜0.75, or 0.3˜0.7. In an embodiment, considering the yield of wafer dicing, the first length L3 can be smaller than the second length L4.

In order to improve the light extraction efficiency of the light-emitting device 1c, in an embodiment, in the side view of the light-emitting device 1c, the mirror portion 1101 passing through the first dicing area 12 is located between two adjacent first dicing portions.

In order to improve the light extraction efficiency of the light-emitting device 1a, 1b, or 1c, in an embodiment, in the side view of the light-emitting device 1a, 1b, or 1c, as shown in FIG. 1A, FIG. 2, and FIG. 3, the first dicing area 12 adjacent to two opposite sides 110 of the side surface 110s of the substrate 10 includes a roughness standard deviation (RMS) that is greater than that of the first dicing area 12 away from the two opposite sides 110 of the side surface 110s of the substrate 10.

Taking the light-emitting device 1a as a representative, FIG. 4 illustrates a relationship between a distance D under the upper surface 110t of the substrate 10 where the first dicing area 12 of the light-emitting device 1a is located and the light extraction efficiency (%) thereof in accordance with an embodiment of the present application. As shown in FIG. 4, the positions of the first dicing area 12 and/or the second dicing area 14 change the traveling direction of the light emitted from the semiconductor stack 20. When the first dicing area 12 and/or the second dicing area 14 is closer to the upper surface 110t of the substrate 10, in other words, the distance D between the first dicing area 12 and/or the second dicing area 14 and the upper surface 110t of the substrate 10 is smaller, more of the light escapes from the upper surface 110t of the substrate 10, and the higher the light extraction efficiency (LEE) of the light-emitting device 1a, 1b, or 1c is.

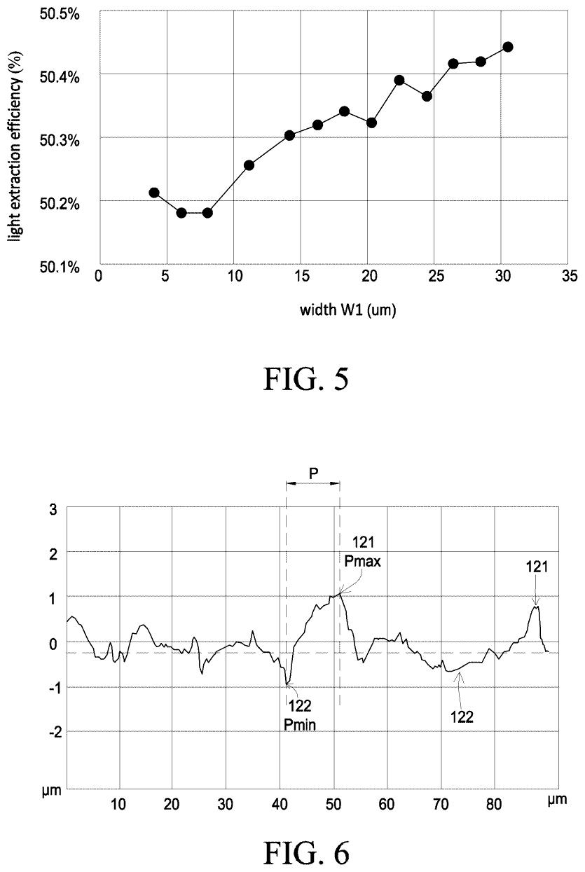

Taking the light-emitting device 1a as a representative, FIG. 5 illustrates a relationship between the first dicing width W1 of the first dicing area 12 of the light-emitting device 1a and the light extraction efficiency (%) thereof. Because the first dicing area 12 absorbs the light, the smaller the first dicing width W1 is, the less the light absorption effect of the first dicing area 12 is. The first dicing width W1 of the first dicing area 12 has a positive correlation with the light scattering area. The larger the light scattering area is, the higher the probability that the light traveling direction can be changed. On the contrary, the smaller the light scattering area is, the lower the probability that the light traveling direction can be changed. As shown in FIG. 5, when the first dicing width W1 of the first dicing area 12 is narrower, the light extraction efficiency (LEE) of the light-emitting device 1a, 1b, or 1c is lower. On the contrary, when the first dicing width W1 the dicing area 12 is wider, the higher the light extraction efficiency (LEE) of the light-emitting device 1a, 1b, or 1c is.

In the manufacturing process of the light-emitting device, the circular wafer is divided into a plurality of rectangular-shaped chips by laser dicing along two mutually perpendicular directions. The two mutually perpendicular directions respectively correspond to a first surface S1 and a second surface S2 of the substrate 10. In an embodiment of the present application, the substrate 10 can be a wafer including a hexagonal crystal system material having a c-plane, such as a sapphire (Al₂O₃) wafer. In the dicing process, taking a rectangular-shaped light-emitting device as an example, the laser dicing is performed along the direction parallel to the flat edge (a-plane) of the sapphire wafer and along the direction perpendicular the flat edge. The light-emitting device after dicing and cleaving includes two opposite first surfaces S1 (for example, r-plane) and two opposite second surfaces S2 (for example, a-plane). Since the r-plane is not perpendicular the c-plane, taking the sapphire as an example, an oblique angle between the r-plane and the c-axis is between 5° and 10° (for example, an oblique angle of about 7°), which makes the wafer difficult to segment. During the process of cleaving the wafer into the chips, there is a deviation between the predetermined cleavage position and the actual cleavage position. In order to increase the throughput of the chips on one wafer, the width of the scribe line on the wafer provided for the laser dicing must be reduced. As the width of the scribe line becomes smaller and smaller, if the actual cleavage position deviates too far from the predetermined cleavage position due to oblique cracks along the lattice plane, the oblique cracks can damage the light-emitting area and the electrode area of the chip, which causes low yield. In another embodiment of the present application, a light-emitting device includes a structure similar to the light-emitting device 1c illustrated in FIG. 3, which will be described below by using the light-emitting device 1c as an example and illustrates with the same structure symbols. The light-emitting device of the embodiment includes a mirror area 11 similar to that of the light-emitting device 1c, including the plurality of mirror portions 1101 passing through the first dicing area 12 to form the plurality of first dicing portions 1200, and the plurality of mirror portions 1101 and the plurality of first dicing portions 1200 are alternately arranged in a direction parallel to the upper surface 110t (the X direction shown in FIG. 3). In the embodiment, the mirror area and the mirror portion refer to an area or a portion including a flat surface having a surface roughness smaller in dimension, such as including a roughness standard deviation (RMS) less than 150 nanometers (nm). In the embodiment, the laser irradiates from the upper surface 110t of the substrate 10, focuses on the interior of the substrate 10, moves along the boundary line of the light-emitting device 1c (for example, the X direction in FIG. 3), and the period of the laser irradiation switch is controlled to form the plurality of first dicing portions 1200. When the laser irradiation switch is turned on, the laser is focused on the interior of the substrate 10 to form the first dicing portion 1200, and the mirror portion 1101 is formed when the laser irradiation switch is turned off.

In an embodiment of the present application, the substrate 10 includes two opposite first surfaces S1 connected to the upper surface 110t and the lower surface 110b of the substrate 10, and two opposite second surfaces S2 connected to the upper surface 110t and the lower surface 110b of the substrate 10. The side surface 110s illustrated in FIG. 3 can be the first surface S1. The side 110 illustrated in FIG. 3 can be the intersection between the first surface S1 and the second surface S2. In the top view of the light-emitting device 1c (not shown), an angle formed between two adjacent first surfaces S1 and second surfaces S2 ranges from 85° ˜95° or 75° ˜105°. In a perspective view of the light-emitting device 1c (not shown), the first surface S1 is connected to the upper surface 110t to form a first side and the second surface S2 is connected to the upper surface 110t to form a second side. The intersections between the two first surfaces S1, the two second surfaces S2 and the upper surface 110t constitute the four sides of the upper surface 110t. The angle between any two adjacent sides of the four sides of the upper surface 110t is between 85° ˜95° or between 75° ˜105°. In other words, the light-emitting device 1c includes a square, rectangle, rhombus, parallelogram, rhombus, rectangle or kite shape in the top view.

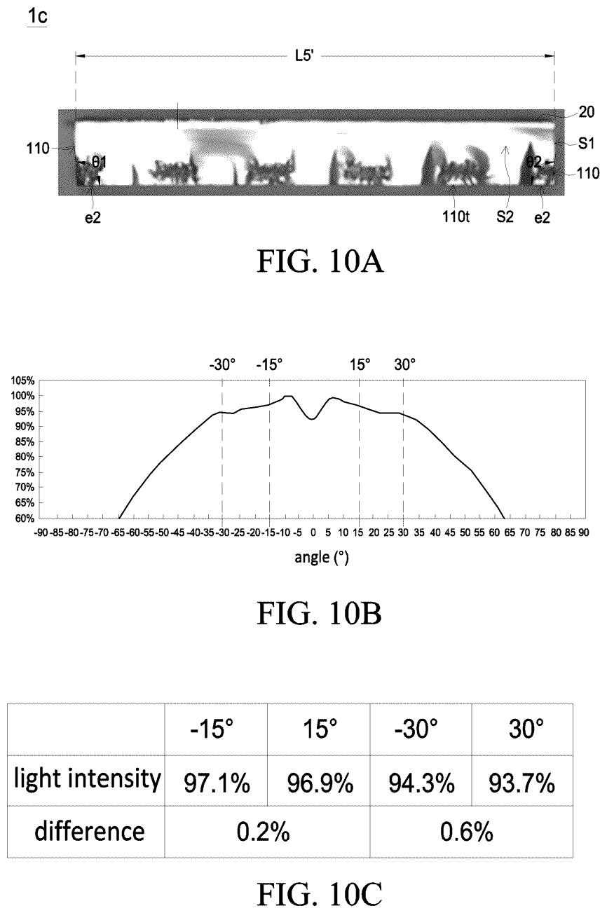

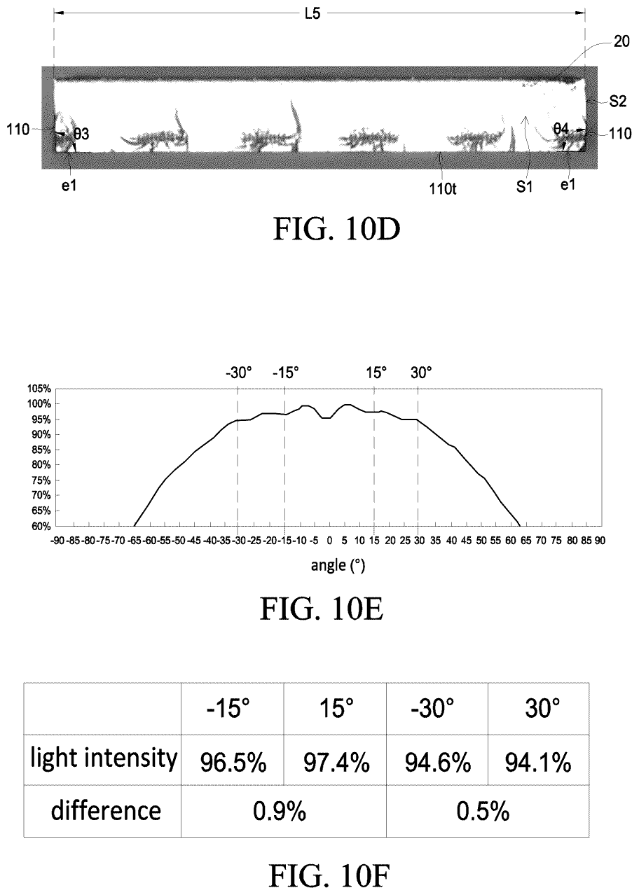

In an embodiment of the present application, the first surface S1 is the r-plane of the sapphire (Al₂O₃) wafer and the upper surface 110t is the c-plane of the sapphire (Al₂O₃) wafer. FIG. 10A illustrates an SEM photograph of the side surface of the substrate of the light-emitting device 1c divided by the abovementioned laser dicing, which shows the oblique crack morphology of the first surface S1 (r-plane) viewed from the second surface S2 of the light-emitting device 1c. In an embodiment, as shown in FIG. 10A, when viewed from the second surface S2 of the light-emitting device 1c, an angle θ1 or θ2 formed between the first surface S1 and the upper surface 110t of the substrate 10 is between 85° ˜95°, in other words, the angle θ1 or 02 between the side 110 and the second side e2 intersected by the second surface S2 and the upper surface 110t is between 85° ˜95°. As shown in FIG. 10D, when viewed from the first surface S1 of the light-emitting device 1c, an angle θ3 or θ4 formed between the second surface S2 and the upper surface 110t of the substrate 10 is between 85° ˜95°, in other words, the angle θ3 or θ4 between the side 110 and the first side e1 intersected by the first surface S1 and the upper surface 110t is between 85° ˜95°. In the embodiment, the angle difference between the angle θ1 or 02 and the angle θ3 or θ4 is less than 12%.

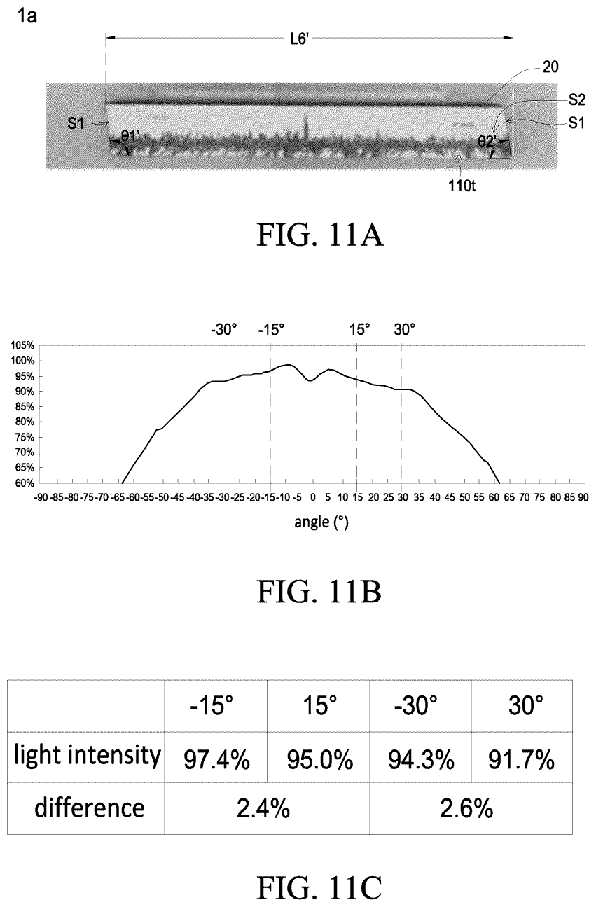

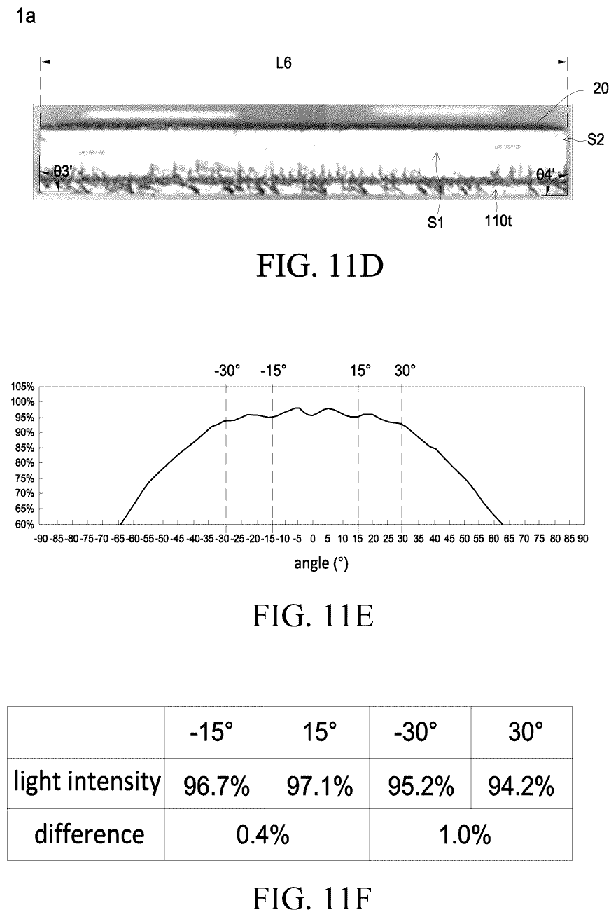

In another embodiment of the present application, the laser irradiates from the upper surface 110t of the substrate 10, focuses on the interior of the substrate 10, moves along the boundary line of the light-emitting device 1a (for example, the X direction in FIG. 1A), and the laser irradiation switch is controlled to form the concave-convex structure 120 illustrated in FIG. 1A. FIG. 11A illustrates an SEM photograph of the side surface of the substrate after laser dicing, and the oblique crack morphology of the first surface S1 (r-plane) is viewed from the second surface S2 of the light-emitting device 1a. In an embodiment, as shown in FIG. 11A, when viewed from the second surface S2 of the light-emitting device 1a, the angles θ1′ and θ2′ respectively formed between the two opposite first surfaces S1 and the upper surface 110t of the substrate 10 is each between 80° ˜100°. As shown in FIG. 11D, when viewed from the first surface S1 of the light-emitting device 1a, the two opposite second surfaces S2 and the upper surface 110t of the substrate 10 respectively include the angles θ3′ and θ4′, wherein each is between 85° ˜95°. In view of the second surfaces S2 of the light-emitting devices 1a and 1c, compared with the light-emitting device 1c, the angle θ1′ or θ2′ of the light-emitting device 1a is larger than the angle θ1 or 02 of the light-emitting device 1c. In view of the first surfaces S1 of the light-emitting devices 1a and 1c, the angle θ3′ or θ4′ of the light-emitting device 1a is substantially the same as the angle θ3 or 04 of the light-emitting device 1c. In the embodiment, the angle difference between the angle θ1′ (or θ2′) and the angle θ3′ (or θ4′) is larger than 12%.

Because the r-plane is easily oblique cracked with an angle non-perpendicular to the c-plane, the two opposite first surfaces S1 each includes the angle θ1 or 02 (the angle between the r-plane and the c-axis) in the side view. FIG. 8 illustrates the angle between the first surface S1 and the upper surface 110t of the substrate 10 in view of the second surface S2 of the light-emitting devices 1a and 1c, and compares the angle between the first surface S1 and the upper surface 110t of the light-emitting devices 1a and 1c. As shown in FIG. 3 and FIG. 8, by adjusting the period of the laser irradiation switch, the light-emitting device 1c includes the plurality of first dicing portions 1200 arranged at intervals, thereby controlling the oblique angles of the substrate 10 after cleavage. The angles θ1 and θ2 of the light-emitting device 1c are respectively closer to 90° than the angles θ1′ and θ2′ of the light-emitting device 1a. As shown in FIG. 3 and FIG. 8, there is a mirror portion 1101 between two adjacent first dicing portions 1200. In an embodiment, when the second length L4 of the mirror portion 1101 is greater than the first length L3 of the first dicing portion 1200, the angles θ1 and θ2 of the light-emitting device 1c can be respectively closer to 90°.

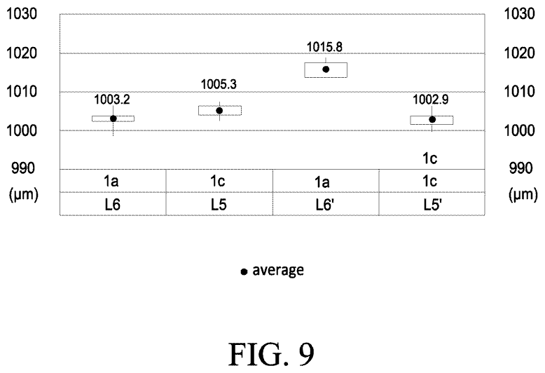

Taking a square chip with a side having a length of 1000 μm as an example, FIG. 9 compares the measured lengths of the sides of the light-emitting device 1a and the light-emitting device 1c. As shown in FIG. 9 and FIG. 11D, when viewed from the first surface S1 of the light-emitting device 1a, the length L6 (1003.2 μm) of the side of the first surface S1 of the light-emitting device 1a measured in the side view is close to the predetermined design length (1000 μm) of the side. As shown in FIG. 9 and FIG. 11A, when viewed from the second surface S2 of the light-emitting device 1a, because the r-plane is easily oblique cracked with an angle non-perpendicular to the c-plane, the length L6′ (1015.8 μm) of the side of the second surface S2 of the light-emitting device 1a measured in the side view deviates from the predetermined design side length (1000 μm). Compared with the r-plane, the a-plane is not easily oblique cracked and the a-plane is perpendicular to the c-plane, so that the length L6 (1003.2 μm) of the side of the first surface S1 of the light-emitting device 1a measured in the side view is close to the predetermined design length (1000 μm) than the length L6′ (1015.8 μm) to the predetermined design length (1000 μm). Compared with the light-emitting device 1a, as shown in FIG. 9, FIG. 10A and FIG. 10D, the length L5 (1005.3 μm) of the side of the first surface S1 measured in the side view or the length L5′ (1002.9 μm) of the side of the second surface S2 of the light-emitting device 1c is closer to the predetermined design length (1000 μm) than that of the light-emitting device 1a.

Referring to FIG. 10A and FIG. 10B, when viewed from the second surface S2 of the light-emitting device 1c, FIG. 10B illustrates a relationship curve between the light intensity and the luminous angle of the light emitted from the light-emitting device 1c viewed in the first direction (such as the Z direction in FIG. 3). Referring to FIG. 3, at the center position of the plane formed by the X direction and the Z direction of the light-emitting device 1c, the Y direction at this position is defined as a main axis of the light. FIG. 10C illustrates the light intensity at ±15 and ±30 degrees off the main axis of the light viewed in the first direction. When viewed from the second surface S2 (for example, the a-plane), the difference between the light intensity (93.7%) measured at +30° off the main axis of the light and the light intensity (94.3%) measured at −30° off the main axis of the light is less than 2%. The difference between the light intensity (96.9%) measured at +15° off the main axis of the light and the light intensity (97.1%) measured at −15° off the main axis of the light is less than 2%. Referring to FIG. 10D and FIG. 10E, when viewed from the first surface S1 of the light-emitting device 1c, FIG. 10E illustrates a relationship curve between the light intensity and the luminous angle of the light emitted from the light-emitting device 1c viewed in the second direction (such as the X direction in FIG. 3). Referring to FIG. 3, at the center position of the plane formed by the X direction and the Z direction of the light-emitting device 1c, the Y direction at this position is defined as the main axis of the light. FIG. 10F illustrates the light intensity at +15 degrees and +30 degrees off the main axis of the light. When viewed from the first surface S1 (for example, the r-plane), the difference between the light intensity (94.1%) measured at +30° of the main axis of the light and the light intensity (94.6%) measured at −30° off the main axis of the light is less than 2%. The difference between the light intensity (97.4%) measured at +15° off the main axis of the light and the light intensity (96.5%) measured at −15° off the main axis of the light is less than 2%.

Referring to FIG. 11A and FIG. 11B, when viewed from the second surface S2 of the light-emitting device 1a, FIG. 11B illustrates a relationship curve between the light intensity and the luminous angle of the light emitted from the light-emitting device 1a viewed in the first direction (such as the Z direction in FIG. 1). Referring to FIG. 1, at the center position of the plane formed by the X direction and the Z direction of the light-emitting device 1a, the Y direction at this position is defined as the main axis of the light. FIG. 11C illustrates the light intensity at ±15 and ±30 degrees off the main axis of the light viewed in the first direction. When viewed from the second surface S2 (for example, a-plane), the difference between the light intensity (91.7%) measured at +30° off the main axis of the light and the light intensity (94.3%) measured at −30° off the main axis of the light is more than 2%. The difference between the light intensity (95.0%) measured at +15° off the main axis of the light and the light intensity (97.4%) measured at −15° off the main axis of the light is more than 2%. Referring to FIG. 11D and FIG. 11E, when viewed from the first surface S1 of the light-emitting device 1a, FIG. 11E illustrates a relationship curve between the light intensity and the luminous angle of the light emitted in the second direction (such as the X direction in FIG. 1). Referring to FIG. 1, at the center position of the plane formed by the X direction and Z direction of the light-emitting device 1a, the Y direction at this position is defined as the main axis of the light. FIG. 11F illustrates the light intensity at +15 degrees and +30 degrees off the main axis of the light. When viewed from the first surface S1 (for example, the r-plane), the difference between the light intensity (94.2%) measured at +30° of the main axis off the light and the light intensity (95.2%) measured at −30° off the main axis of the light is less than 2%. The difference between the light intensity (97.1%) measured at +15° off the main axis of the light and the light intensity (96.7%) measured at −15° off the main axis of the light is less than 2%. Because the difference between the light intensity of the light-emitting device 1c measured at ±30° or ±15° along the main axis of the light in the first direction and the light intensity measured at ±30° or ±15° along the main axis of the light in the second direction is both less than 2%, the light-emitting device 1c can provide a more symmetrical light field shape than the light-emitting device 1a.

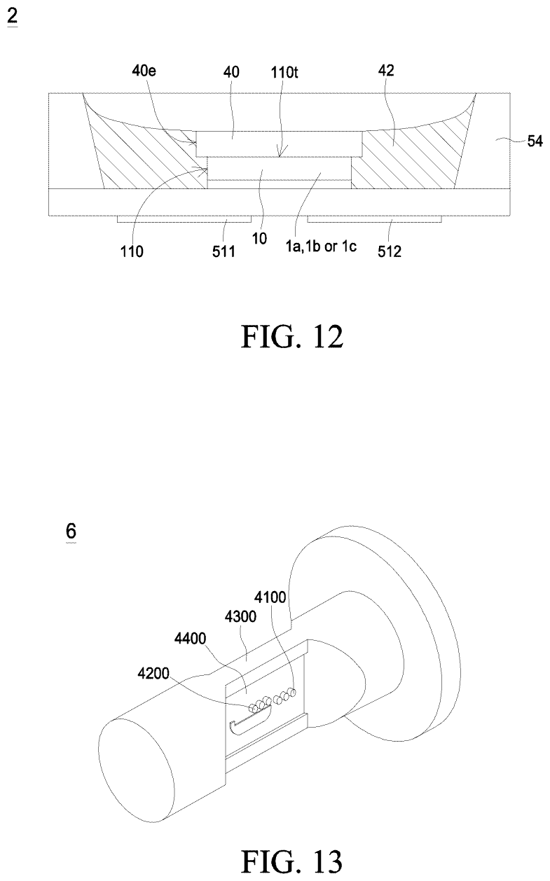

FIG. 12 illustrates a schematic diagram of a light-emitting apparatus 2 according to an embodiment of the present application. The light-emitting device 1a, 1b, or 1c in the foregoing embodiments is mounted on a first spacer 511 and a second spacer 512 of a packaging substrate 54 in the form of a flip chip. The first spacer 511 and the second spacer 512 are electrically insulated from each other by an insulating part (not shown) containing the insulating material. In the flip-chip mounting, the upper surface 110t of the substrate 10 is provided as the main light extraction surface.

As shown in FIG. 12, an optical structure 40 is located on the upper surface 110t of the substrate 10 and a reflective structure 42 is formed on the side surface of the first dicing area 12 and the first crack area 13 of the substrate 10. The optical structure 40 can be a layered structure, including an edge 40e protruding or retracting from both sides 110 of the substrate 10.

In an embodiment, when the light-emitting layer 23 of the light-emitting device 1a, 1b, or 1c includes gallium nitride (GaN) or aluminum gallium nitride (AlGaN) material, so that the light-emitting layer 23 can emit the blue light, the optical structure 40 including a wavelength conversion material, such as Ce-doped yttrium aluminum garnet (YAG) phosphor that can absorb the blue light emitted from the light-emitting layer 23 and convert the blue light into the white light.

The reflective structure 42 can reflect the light escaping from the side surface 110s of the substrate 10, direct the light to emit from the upper surface 110t of the substrate 10, thereby avoiding the light emitted from the light-emitting device 1a, 1b, or 1c not passing through the optical structure 40 that may reduce the light extraction of the white light of light-emitting apparatus 2. In an embodiment, the reflective structure 42 includes a metal material and is partially formed on the side surface 110s of the substrate 10. In an embodiment, the reflective structure 42 includes a highly reflective material that is not conductive. For example, the highly reflective material can be formed by adding TiOx, AlxOy, or ZrOx into polysiloxane, epoxy resin, or sol-gel.

According to the embodiments of the present application, the light from the light-emitting device 1a, 1b, or 1c can be gathered and emitted from the upper surface 110t of the substrate 10, so that the light can pass through the optical structure 40, thereby increasing the amount of the light that the optical structure 40 can capture, and the extraction efficiency of the white light is improved.

FIG. 13 illustrates a schematic diagram of a light emitting apparatus 6 according to an embodiment of the present application. In the embodiment, the light-emitting apparatus 6 is provided for an LED bulb of the automobile, which can be plugged and fixed into the mounting hole on the rear shell of the automobile headlight assembly. The light-emitting apparatus 6 includes a first LED chip 4100 for low beam lighting or a second LED chip 4200 for high beam lighting, a long columnar lamp post 4300, a driving power circuit board 4400, and a heat dissipation fins for heat dissipation (not shown), a fan (not shown) for heat dissipation, a fan cover (not shown) for protecting the fan, and a power line (not shown) for electrical connecting with the vehicle battery which are arranged on the power supply, and a plug at the end of the power supply (not shown). The first LED chip 4100 or the second LED chip 4200 in the light-emitting apparatus 6 can include any one or more of the aforementioned light-emitting devices 1a, 1b, or 1c or the light-emitting apparatus 2.

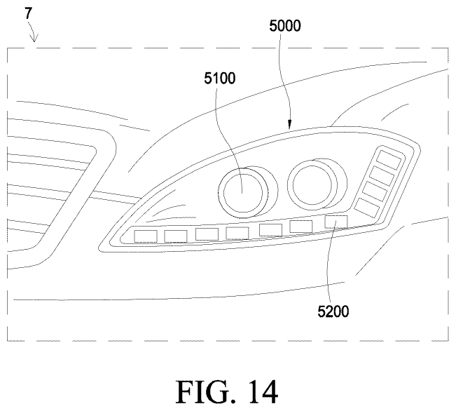

FIG. 14 illustrates a schematic diagram of a light emitting apparatus 7 according to an embodiment of the present application. In the embodiment, the light-emitting apparatus 7 can be a vehicle lighting lamp 5000, which can be applied in the daytime running light, the headlight, the tail light, or the direction indicator light. The main lighting lamp 5100 can be a major light-emitting lamp in the vehicle lighting lamp 5000. For example, when the vehicle lighting lamp 5000 is provided as the headlight, the main lighting lamp 5100 functions the headlight that illuminates the front of the vehicle. The combination lighting lamp 5200 includes at least two functions. For example, when the vehicle lighting lamp is provided as the headlight, the combination lighting lamp 5200 functions the daytime running light (DRL) and the direction indicator light. The main lighting lamp 5100 or the combination lighting lamp 5200 can include any one or more of the aforementioned light-emitting devices 1a, 1b, or 1c or the light-emitting apparatus 2.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A light-emitting device, including:
a semiconductor stack;
a substrate located on the semiconductor stack, including a lower surface connected to the semiconductor stack, an upper surface opposite to the lower surface and a side surface located between the lower surface and the upper surface, wherein the side surface includes a mirror area, a first dicing area, and a first crack area, the mirror area is closer to the lower surface than the first dicing area to the lower surface, and the first dicing area is located between the mirror area and the first crack area;
an optical structure located on the upper surface of the substrate; and
a reflective structure located on a side surface of the first dicing area and the first crack area, wherein the first dicing area is located below the upper surface of the substrate at a distance less than or equal to ¼ of a thickness of the substrate.

2. The light-emitting device according to claim 1, wherein the mirror area includes a width greater than 75 μm.

3. The light-emitting device according to claim 1, wherein the first dicing area includes a first dicing width between 4 μm and 30 μm.

4. The light-emitting device according to claim 1, wherein the first dicing area is located below the upper surface of the substrate at a distance less than 45 μm.

5. The light-emitting device according to claim 1, wherein the first dicing area is located below the upper surface of the substrate at a distance less than 25 μm, and the distance is larger than 1 μm.

6. The light-emitting device according to claim 1, wherein the first dicing area and the first crack area include a total width smaller than a total width of the mirror area.

7. The light-emitting device according to claim 1, wherein the first dicing area includes a roughness standard deviation (RMS) larger than a roughness standard deviation (RMS) of the first crack area, and the roughness standard deviation (RMS) of the first crack area is larger than a roughness standard deviation (RMS) of the mirror area.

8. The light-emitting device according to claim 1, wherein the first dicing area includes a plurality of dicing convex portions and/or a plurality of dicing concave portions, and the first crack area includes a plurality of crack convex portions and/or a plurality of crack concave portions extending to the upper surface of the substrate from the first dicing area.

9. The light-emitting device according to claim 8, wherein the plurality of dicing convex portions and/or the plurality of dicing concave portions include an amount or a size larger than an amount or a size of the plurality of crack convex portions and/or the plurality of crack concave portions.

10. The light-emitting device according to claim 8, wherein a minimum distance between the plurality of dicing convex portions and/or the plurality of dicing concave portions is smaller than a minimum distance between the plurality of crack convex portions and/or the plurality of crack concave portions.

11. The light-emitting device according to claim 1, wherein the mirror area includes a plurality of mirror portions passing through the first dicing area to form a plurality of first dicing portions, and one of the plurality of mirror portions is located between two adjacent first dicing portions.

12. The light-emitting device according to claim 11, wherein one of the plurality of first dicing portions includes a first length larger than a second length of one of the plurality of mirror portions in a direction parallel to the upper surface.

13. The light-emitting device according to claim 12, wherein the mirror portion includes a length of 0.5 to 0.8 times a length of one side of the light-emitting device in a side view of the light-emitting device.

14. The light-emitting device according to claim 1, wherein in a side view of the light-emitting device, the side surface includes two edges, and the first dicing area adjacent to the two edges of the substrate includes a roughness standard deviation (RMS) larger than a roughness standard deviation (RMS) of the first dicing area away from the two sides of the substrate.

15. The light-emitting device according to claim 1, further including a second dicing area located between the first dicing area and the upper surface of the substrate.

16. The light-emitting device according to claim 15, wherein the first crack area is located between the first dicing area and the second dicing area.

17. The light-emitting device according to claim 15, wherein the first dicing area includes a first width larger than a second width of the second dicing area.

18. The light-emitting device according to claim 15, wherein the first dicing area includes a first width smaller than a second width of the second dicing area.

19. The light-emitting device according to claim 15, wherein the first dicing area includes a first width that is the same as a second width of the second dicing area.

20. The light-emitting device according to claim 1, wherein the optical structure contains a wavelength conversion material and includes a layered structure.
